(19) United States
(12) Patent Application Publication
(10) Pub. No.: US 2020/0064961 A1
(43) Pub. Date: Feb. 27, 2020

(54) INPUT DEVICE

(71) Applicant: FUJITSU COMPONENT LIMITED, Tokyo (JP)

(72) Inventors: Kazuhiro YASUNO, Tokyo (JP); Katsuya FUNAKOSHI, Tokyo (JP); Maiko KIKUCHI, Tokyo (JP)

(73) Assignee: FUJITSU COMPONENT LIMITED, Tokyo (JP)

(21) Appl. No.: 16/449,834

(22) Filed: Jun. 24, 2019

(30) Foreign Application Priority Data
Aug. 24, 2018 (JP) 2018-156897

(51) Int. Cl. G06F 3/041; G06F 3/044; H03K 17/96; G06F 3/02

(52) U.S. Cl. CPC G06F 3/0416; G06F 3/044; H03K 2217/94026; G06F 3/0202; H03K 17/9622

(57) ABSTRACT

An input device includes: an inputter including a plurality of keys; a sensitivity controller that determines a sensitivity of input operation to the keys; an input detector that detects the presence or absence of input to the keys based on the input operation and the sensitivity; and an area controller that sets one or more input areas including at least one key to the inputter; wherein the sensitivity controller sets the sensitivity for each input area.

### CROSS-REFERENCE TO RELATED APPLICATION

This application is based upon and claims the benefit of priority of the prior Japanese Patent Application No. 2018-156897 filed on Aug. 24, 2018, the entire contents of which are incorporated herein by reference.

### FIELD

A certain aspect of the embodiments is related to an input device.

### BACKGROUND

In a software keyboard of a tablet or a mobile phone, a touch panel having a flat surface detects the input and inputs key data corresponding to an input position. In a mechanical keyboard, key arrangement is fixed. However, in the software keyboard, the arrangement of key areas can be changed. Moreover, a technique of changing a sensitivity of the input operation for each key area is developed based on the strength of the input operation to the key area (e.g. Patent Document 1: Japanese Laid-open Patent Publication No. 2012-98828, and Patent Document 2: Japanese Laid-open Patent Publication No. 2016-162364).

### SUMMARY

According to a first aspect of the present disclosure, there is provided an input device including: an inputter including a plurality of keys; a sensitivity controller that determines a sensitivity of input operation to the keys; an input detector that detects the presence or absence of input to the keys based on the input operation and the sensitivity; and an area controller that sets one or more input areas including at least one key to the inputter; wherein the sensitivity controller sets the sensitivity for each input area.

According to a second aspect of the present disclosure, there is provided an input device including: an electrostatic capacitance type touch panel including a plurality of keys; a sensitivity controller that determines a sensitivity of input operation to the keys; and an input detector that detects input to the keys when an input value by the input operation is equal to or more than a threshold value; wherein the keys includes a first key and a second key, and the sensitivity controller makes a threshold value corresponding to the first key smaller than a threshold value corresponding to the second key, and an input value when a finger approaches the first key within a predetermined distance.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a block diagram of an input device according to a first embodiment;

FIG. 1B is a functional block diagram of a MCU;

FIG. 2A is a cross-sectional view of a touch panel;

FIG. 2B is a perspective view of the touch panel;

FIG. 3A is a diagram illustrating a relationship of a contact resistance between conductive films and a load;

FIGS. 3B to 3D are schematic views illustrating input operation;

FIGS. 4A to 4C are plan views illustrating a keyboard;

FIGS. 5A and 5B are plan views illustrating the keyboard;

FIG. 6 is a flowchart illustrating setting processing of an area;

FIG. 7 is a flowchart illustrating detection processing of the input;

FIG. 8A is a cross-sectional view of a touch panel;

FIG. 8B is a plan view of the touch panel;

FIG. 9A is a diagram illustrating a change in capacitance;

FIGS. 9B to 9E are schematic views illustrating input operation; and

FIG. 10 is a flowchart illustrating detection processing of the input.

### DESCRIPTION OF EMBODIMENTS

In the above conventional technique, an operation feeling of a user is not sufficient. An input device of the embodiments can improve an operation feeling.

Hereinafter, a description will now be given of embodiments according to the present invention with reference to drawings.

### First Embodiment

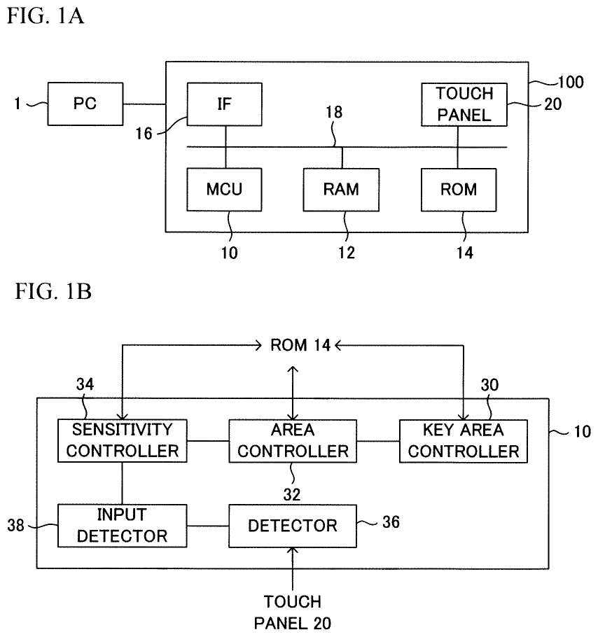

FIG. 1A is a block diagram of an input device 100 according to a first embodiment. The input device 100 of FIG. 1A includes a Micro Control Unit (MCU) 10, a Random Access Memory (RAM) 12, a Read Only Memory (ROM) 14, an interface (IF) 16 and a touch panel 20 which are connected to each other via a bus 18. The input device 100 is an electronic device such as a smartphone or tablet terminal, for example, and can be connected to a personal computer (PC: Personal Computer) 1.

The MCU 10 is an arithmetic unit for controlling the input device 100. The RAM 12 serves as a working area. The ROM 14 stores an operating system (OS), applications, a touch panel driver, and so on, and further stores data of an area described below. The IF 16 is a communication interface. The input device 100 communicates with the PC 1 via the IF 16.

FIG. 1B is a functional block diagram of the MCU 10. The MCU 10 serves as a key area controller 30, an area controller 32, a sensitivity controller 34, a detector 36 and an input detector 38, as illustrated in FIG. 1B. The key area controller 30 performs the setting and the change of key areas in a keyboard to be displayed on the touch panel 20. The area controller 32 sets at least one area in the keyboard to be displayed. The sensitivity controller 34 sets a sensitivity to the input operation of the user for each area. The detector 36 acquires a strength of the input operation such as a contact resistance when the touch panel 20 is touched. The input detector 38 detects the input to the touch panel 20 depending on the contact resistance and the sensitivity.

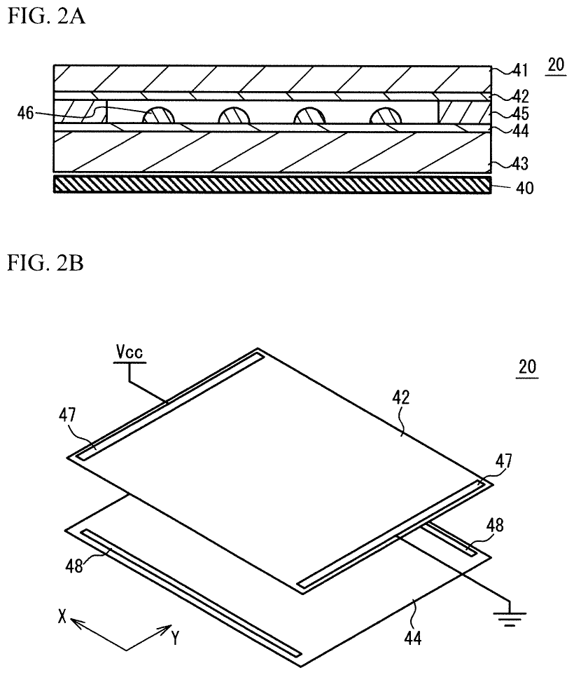

FIG. 2A is a cross-sectional view of the touch panel 20, and FIG. 2B is a perspective view of the touch panel 20. The touch panel 20 is a resistance film type touch panel, and includes substrates 41 and 43, conductive films 42 and 44, an adhesive layer 45 and dot spacers 46. The conductive film 42 is pasted on a lower surface of the substrate 41, and the conductive film 44 is pasted on an upper surface of the substrate 43. The conductive film 42 is separated from the conductive film 44, and a plurality of dot spacers 46 are provided between the conductive films 42 and 44. The conductive film 42 and the conductive film 44 are bonded by the adhesive layer 45 provided on a peripheral portion thereof.

The substrates 41 and 43 are made of transparent material such as glass or resin. The conductive film 42 and 44 are transparent conductive film made of Indium Tin Oxide (ITO), for example. The adhesive layer 45 and the dot spacers 46 are made of an insulator.

A display unit 40 such as a liquid crystal display is superimposed on the substrate 41 and 43, and the user can view a screen of the display unit 40 via the touch panel 20. The keyboard is displayed on the touch panel 20, and an X-coordinate and a Y-coordinate of an operation point of the touch panel 20 are detected in the following manner, which makes it possible to accept the input operation of a software keyboard by the user.

As illustrated in FIG. 2B, electrodes 47 are provided along two sides parallel to a Y-direction of the conductive film 42. Electrodes 48 are provided along two sides parallel to an X-direction of the conductive film 44. The electrodes 47 and 48 are made of a metal such as silver (AG), for example.

When the X-coordinate of a contact point of the conductive films 42 and 44 is detected, one of a pair of electrodes 47 is connected to a power supply Vcc and the other is grounded. This generates a potential gradient in the X-direction. A potential at this time is detected by the electrodes 48, and is input to the MCU 10 via an AD converter, not illustrated. When the Y coordinate of the contact point is detected, one of a pair of electrodes 48 is connected to the power supply Vcc and the other is grounded, and a potential detected by the electrodes 47 is input to the MCU 10. Since the contact resistance between the conductive films is changed by a strength of the user's pressing, the potential to be detected by the electrodes also changes depending on the strength of the pressing.

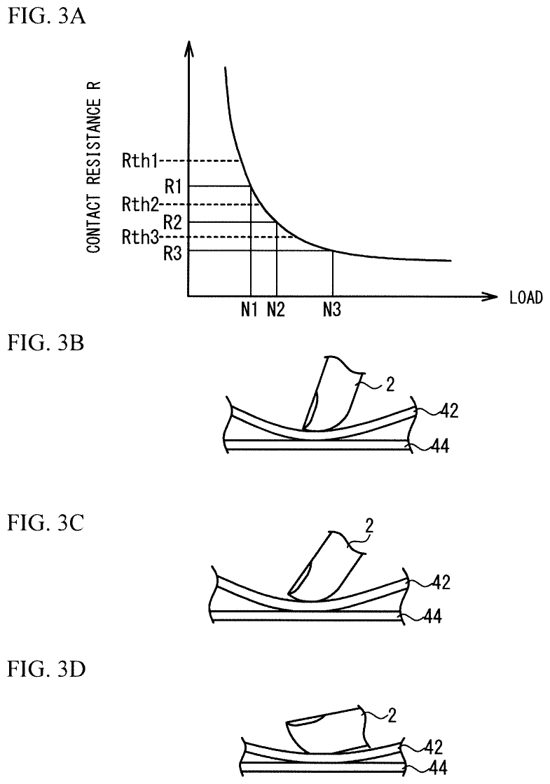

FIG. 3A is a diagram illustrating a relationship of the contact resistance between the conductive films 42 and 44 and a load applied to the conductive film 42. A horizontal axis indicates the load applied to the conductive film 42, and a vertical axis indicates the contact resistance. As illustrated in FIG. 3A, the higher the load, the lower the contact resistance. That is to say, when the user presses the touch panel 20 weakly, a contact area between the conductive films is small and therefore the contact resistance is high. When the user presses the touch panel 20 strongly, the contact area is relatively large and therefore the contact resistance is lowered. In FIG. 3A, the contact resistance is R1 when the load is N1. Rth1 to Rth3 indicate threshold values, and a different threshold value is set for each area in the keyboard, as described below. When the contact resistance is equal to or less than the threshold value set for each key, the input detector 38 detects the key input in the area. Here, the contact resistance is high in the order of Rth1, R1, Rth2, R2, Rth3 and R3. The contact resistance R3 is the lowest.

FIGS. 3B to 3D are schematic views illustrating the input operation. A user's finger 2 and the conductive films 42 and 44 are illustrated. Since the load applied from the finger 2 is increased from FIG. 3B to FIG. 3D, the contact area between the conductive films is increased and the contact resistance is lowered. It is assumed that the load applied from the finger 2 in FIG. 3B is N1 in FIG. 3A and the contact resistance is R1. It is assumed that the load in FIG. 3C is N2 and the contact resistance is R2. It is assumed that the load in FIG. 3D is N3 and the contact resistance is R3. It is possible to determine whether a present state is in any state of FIGS. 3A to 3C by comparing the contact resistance at present time with threshold values Rth1 to Rth3.

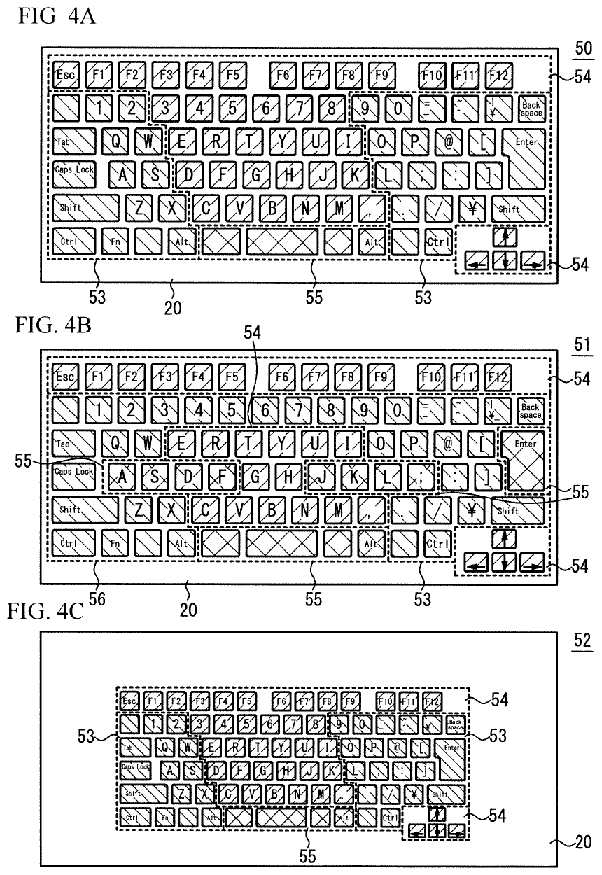

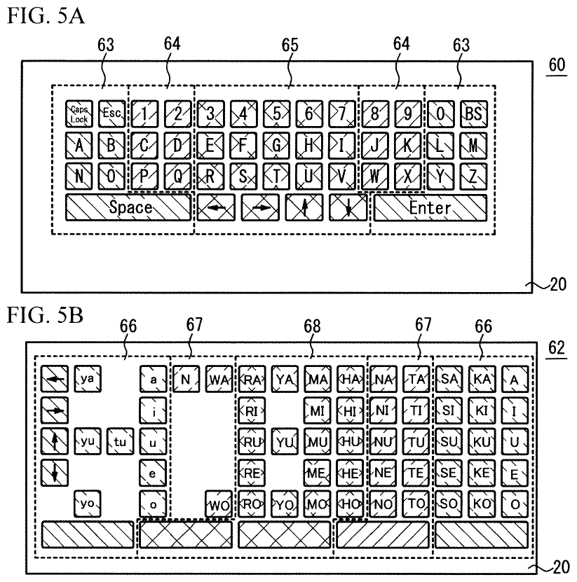

FIGS. 4A to 5B are plan views illustrating the keyboard. A keyboard 50 of FIG. 4A, a keyboard 51 of FIG. 4B and a keyboard 52 of FIG. 4C are software keyboards of QWERTY layout for alphabet input, respectively, and they are displayed on the touch panel 20 by using the display unit 40. Each of the keyboards 50 to 52 includes a plurality of keys such as keys of alphabet “A” to “Z”, direction keys indicating “up”, “down”, “right”, and “left”, an enter key, and a space key. The keyboard 52 of FIG. 4C is smaller than the keyboards 50 and 51, and is a keyboard for a child, for example.

Here, the key layout is not limited to the QWERTY layout. The keyboard 60 of FIG. 5A has ABC layout, and the alphabet keys are arranged in an ABC order from the left. A keyboard 62 of FIG. 5B has Japanese syllabary layout, and includes Japanese syllabary keys.

The load applied to the touch panel 20 by the user is different for each key. For example, in an area where a key to be pressed with a user's little finger is placed, the load is small, thus a contact area also becomes small as illustrated in FIG. 3B, and the contact resistance is approximately the R1, for example. In an area where a key to be pressed with a user's index finger is placed, the load is large, thus the contact area becomes large as illustrated in FIG. 3D, and the contact resistance is approximately the R3, for example.

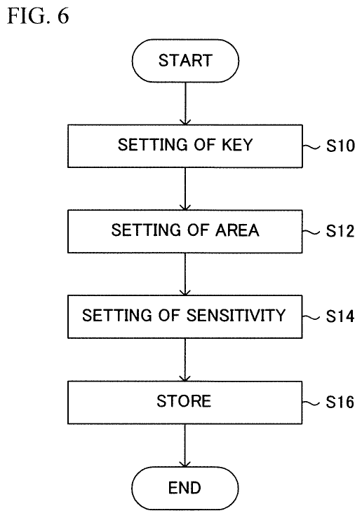

For this reason, in the first embodiment, a plurality of areas are set in the keyboard 50, and the sensitivity to the input operation is changed for each area depending on the load at the time of pressing the touch panel 20 with the finger. FIG. 6 is a flowchart illustrating setting processing of the area. For example, the PC 1 is connected to the input device 100 and the user inputs a setting command from the PC 1, so that the processing of FIG. 6 can be executed.

As illustrated in FIG. 6, the key area controller 30 sets the keys to the keyboard (S10). At this time, the areas for the keys of alphabet “A” to “Z”, the direction keys, the enter key, the space key and the like are set, for example. The area controller 32 sets a plurality of areas in the keyboard (S12). The sensitivity controller 34 sets the sensitivity for each area (S14). The ROM 14 associates the keys, the areas, and the sensitivities that are set in the keyboard with each other to store them (S16). The processing is terminated.

For example, the key area controller 30 sets the keys of the QWERTY layout, as illustrated in FIG. 4A. The area controller 32 sets areas 53 to 55. In FIG.

4A, the areas are separated by a dotted line. The area 53 is indicated by a right down oblique line, and includes character Q, A, and P keys, the Enter key, and so on. The area 54 is indicated by a right up oblique line, and includes character T and Y keys, the direction keys, and so on. The area 55 is indicated by intersected oblique lines, and includes the space key, and so on. The sensitivity controller 34 sets the sensitivity for each of the areas 53 to 55. Thereby, the areas 53 to 55 having different sensitivities with each other are set to the keyboard 50.

The sensitivity corresponds to the threshold value illustrated in FIG. 3A. The higher the threshold value, the higher the sensitivity. The lower the threshold value, the lower the sensitivity. The sensitivity controller 34 increases the sensitivity of the area 53, lowers the sensitivity of the area 54 than that of the area 53, and lowers the sensitivity of the area 55 than that of the area 54. Specifically, the sensitivity controller 34 determines the Rth1 of FIG. 3A as the threshold value of the area 53, determines the Rth2 as the threshold value of the area 54, and determines the Rth3 as the threshold value of the area 55.

The areas 53 to 55 in the keyboard 51 of FIG. 4B are set at positions different from the corresponding areas of the keyboard 50, and the respective threshold values are set as the Rth1 to Rth3. The areas 53 to 55 of the keyboard 52 in FIG. 4C include the same keys as these areas of the keyboard 50.

Areas 63 to 65 are included in a keyboard 60 illustrated in FIG. 5A. Areas 63 are located on end parts of the keyboard 60, an area 65 is located on a central part thereof, and areas 64 are located between the areas 63 and the area 65. Areas 66 to 68 are included in a keyboard 62 illustrated in FIG. 5B. The areas 66, 67 and 68 are arranged from the end parts of the keyboard 62 to the central part thereof. The threshold values of the areas 63 and 66 are the Rth1, the threshold values of the areas 64 and 67 are the Rth2, and the threshold values of the areas 65 and 68 are the Rth3.

Tables 1 to 5 are examples of data tables stored in the ROM 14. These tables include data indicating key layouts for the keyboards 50 to 52, 60 and 62, set areas, and the threshold value for each area, respectively.

TABLE 1

| KEYBOARD | 50 | | |
|---|---|---|---|
| LAYOUT | QWERTY | | |
| AREA | 53 | 54 | 55 |
| THRESHOLD | Rth1 | Rth2 | Rth3 |
| VALUE | | | |

TABLE 2

| KEYBOARD | 51 | | |
|---|---|---|---|
| LAYOUT | QWERTY | | |
| AREA | 53 | 54 | 55 |
| THRESHOLD | Rth1 | Rth2 | Rth3 |
| VALUE | | | |

TABLE 3

| KEYBOARD | 52 | | |
|---|---|---|---|
| LAYOUT | QWERTY | | |
| AREA | 53 | 54 | 55 |
| THRESHOLD | Rth1 | Rth2 | Rth3 |
| VALUE | | | |

TABLE 4

| KEYBOARD | 60 | | |
|---|---|---|---|
| LAYOUT | ABC | | |
| AREA | 63 | 64 | 65 |
| THRESHOLD | Rth1 | Rth2 | Rth3 |
| VALUE | | | |

TABLE 5

| KEYBOARD | 62 | | |
|---|---|---|---|
| LAYOUT | JAPANESE | | |
| | SYLLABARY | | |
| AREA | 66 | 67 | 68 |
| THRESHOLD | Rth1 | Rth2 | Rth3 |
| VALUE | | | |

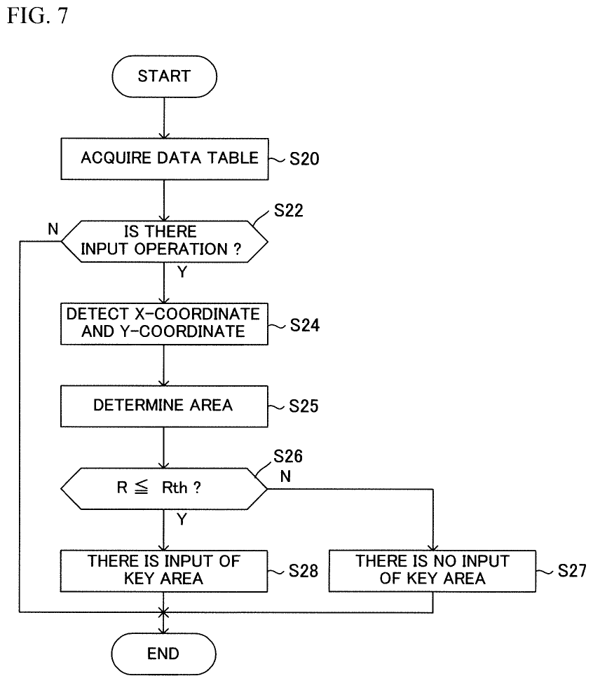

FIG. 7 is a flowchart illustrating detection processing of the input. The MCU 10 acquires the data table corresponding to the keyboard to be displayed from the ROM 14 (S20). The detector 36 determines whether there is input operation to the touch panel 20 (S22). When the answer to the determination of S22 is No, the processing is terminated. When the answer to the determination of S22 is Yes, the MCU 10 advances to processing of S24. If there is a change in the contact resistance for example, the detector 36 determines that there is the input operation.

The detector 36 detects the X-coordinate and the Y-coordinate of an input operation position of the touch panel 20 (S24). The input detector 38 refers to the data table, and determines an area including the input operation position (S25). Next, the input detector 38 determines whether the contact resistance R at the time of the input operation is equal to or less than the threshold value Rth (S26). Any one of the Rth1 to Rth3 is assigned to the threshold value Rth depending on the area.

When the answer to the determination of S26 is No, the input detector 38 determines that there is no key input (S27). On the other hand, when the answer to the determination of S26 is Yes, the input detector 38 determines that there is key input (S28). The characters and information corresponding to the operated keys are entered. After S27 or S28, the processing is terminated.

When the touch panel 20 displays the keyboard 50 illustrated in FIG. 4A for example, the MCU 10 acquires the data table of the table 1 from the ROM 14, and reads the areas 53 to 55 and the threshold values Rth1 to Rth3. When the user touches the character “S” of the keyboard 50, the X-coordinate and the Y-coordinate corresponding to a “S” key are detected in S24. Since the “S” key is included in the area 53, the input detector 38 selects the Rth1 as the threshold value. When the contact resistance R at the time of pressing the key is equal to or less than the threshold value Rth1, the input detector 38 detects the input of the character “S”.

Also, when the user touches the space key, the input detector 38 selects the Rth3 as the threshold value. When the contact resistance at the time of touching the space key is greater than the Rth3, the input detector 38 does not detect the key input. On the other hand, when the finger 2 strongly touches the touch panel 20 as illustrated in FIG. 3D and the contact resistance is equal to or less than the Rth3, the input detector 38 detects the key input.

According to the first embodiment, the sensitivity controller 34 changes the threshold value for each of the areas 53 to 53 of the keyboard 50, and the input detector 38 detects the key input based on the contact resistance and the threshold value set to each area. For example, the area 53 has a high threshold value and a high sensitivity. For this reason, even if the user lightly touches the touch panel 20 as illustrated in FIG. 3B, the input detector 38 detects the input. On the other hand, since the sensitivity of the area 54 is lower than that of the area 53, when the user strongly touches the touch panel 20 as illustrated in FIG. 3C, the input detector 38 detects the input. The sensitivity of the area 55 is further lower than that of the area 54. For this reason, when the user more strongly touches the touch panel 20 as illustrated in FIG. 3D, the input detector 38 detects the input. As described above, the areas having different sensitivities are set, so that an operation feeling is improved.

As illustrated in FIGS. 4A to 5B, each area preferably includes two or more adjacent keys. Thereby, the same sensitivity is set to the plurality of adjacent keys, the user can enter these keys by touching them with the same level of strength, and the operation feeling is improved. Also, since an amount of data to be set to the data table is reduced as compared with the case of setting the sensitivity for each key, it is possible to reduce a memory capacity to be occupied. The load of the user at the time of the setting is also reduced.

It is preferable to provide high sensitivity areas on the end parts of the keyboard and provide a low sensitivity area on the central part thereof. The user may strongly press the keys on the central part of the keyboard, and may weakly press the keys on the end parts thereof. The areas corresponding to the strength of the pressing are determined, so that the operation feeling is further improved.

The area controller 32 may determine the areas based on the placement of the user's fingers on the touch panel 20. Since the loads applied to the touch panel 20 are different depending on the fingers to be touched, the sensitivities to be set to respective areas also are changed depending on the fingers. Thereby, the operation feeling is improved.

For example, it is considered that, in the keyboard 50 illustrated in FIG. 4A, the keys “Q” and “P” close to the user's pinky are weakly pressed. Therefore, the area controller 32 sets these keys in the area 53, and the sensitivity controller 34 increases the sensitivity of the area 53. On the other hand, it is considered that the key “T” close to the index finger and the space key close to the thumb are pressed strongly as compared with a case to be operated with the pinky. Therefore, the area controller 32 sets these keys in the area 55, and the sensitivity controller 34 decreases the sensitivity of the area 55. Thereby, the operation feeling is improved.

The sensitivity controller 34 may appropriately change the sensitivities of the areas. For example, the threshold value for the area 53 of the keyboard 50 is made higher than the Rth1, so that it is possible to increase the sensitivity of the area 53. Moreover, the threshold value for the area 55 is made lower than the Rth1, so that it is also possible to decrease the sensitivity of the area 55. It is also possible to increase the sensitivity of the area used high-frequently by the user, and to decrease the sensitivity of the area used low-frequently. Thus, since the user can arbitrarily change the sensitivity for each area, the operation feeling is improved.

The key area controller 30 determines the keys, so that the keyboards 50 to 52 of the QWERTY layout, the keyboard 60 of the ABC layout, or the keyboard 62 of the Japanese syllabary layout as illustrated in FIGS. 4A to 5B can be displayed on the touch panel 20. Also, it is also possible to configure the keyboard 52 having the same key layout as the keyboard 50 and a size smaller than the keyboard 50. Thereby, it is possible to change the keyboard depending on the size of the user's hand and the characters which the user wants to input, and the operation feeling is improved.

### Second Embodiment

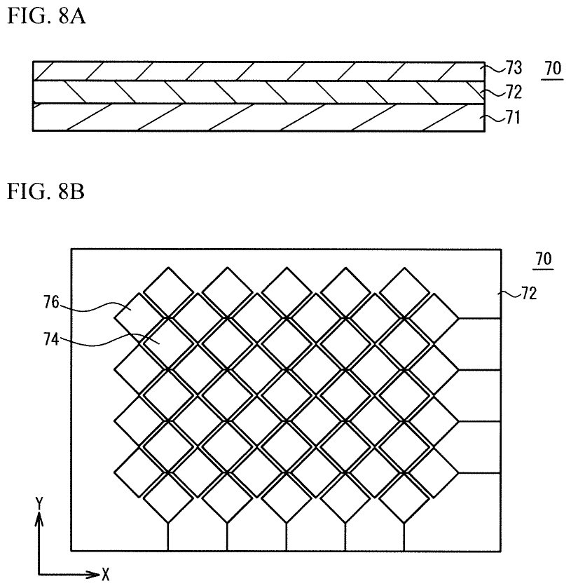

A second embodiment indicates an example of using a projection capacitive type touch panel 70 in place of the resistance film type touch panel 20. The configuration other than the touch panel is the same as the first embodiment. FIG. 8A is a cross-sectional view of the touch panel 70, and FIG. 8B is a plan view of the touch panel 70. The touch panel 70 includes a substrate 71, an electrode layer 72 and a protective layer 73, as illustrated in FIG. 8A. The electrode layer 72 is pasted on the substrate 71, and the protective layer 73 covers the electrode layer 72. The substrate 71 is made of a glass, the electrode layer 72 is made of the ITO, and the protective layer 73 is made of an insulator. They are transparent. As described in the first embodiment, any of the keyboards 50 to 52, 60 and 62 is displayed on the touch panel 70.

As illustrated in FIG. 8B, the electrode layer 72 has patterns of a plurality of electrodes 74 and 76. Planar shapes of the electrodes 74 and 76 are rhombuses for example, and are arranged in an X-axis direction and a Y-axis direction. The electrodes 74 are electrodes for detecting an X-coordinate, and the electrodes 76 are electrodes for detecting a Y-coordinate. Wirings are extended from the electrodes 74 and 76 located on an outermost of the touch panel 70, and are connected to the MCU 10. The electrodes 74 adjacent in the vertical direction in the figure are electrically connected by the wirings, and the electrodes 76 adjacent in the horizontal direction in the figure are electrically connected by the wirings. The electrodes 74 and 76 adjacent to each other are not electrically connected and are separated.

When the user's finger touches a surface of the touch panel 20, a capacitance is generated between the finger and the electrodes 74 and 76. Thereby, the capacitance between the electrodes is increased as compared with a case where there is no touch of the user. It is possible to detect the input position by such a change in capacitance.

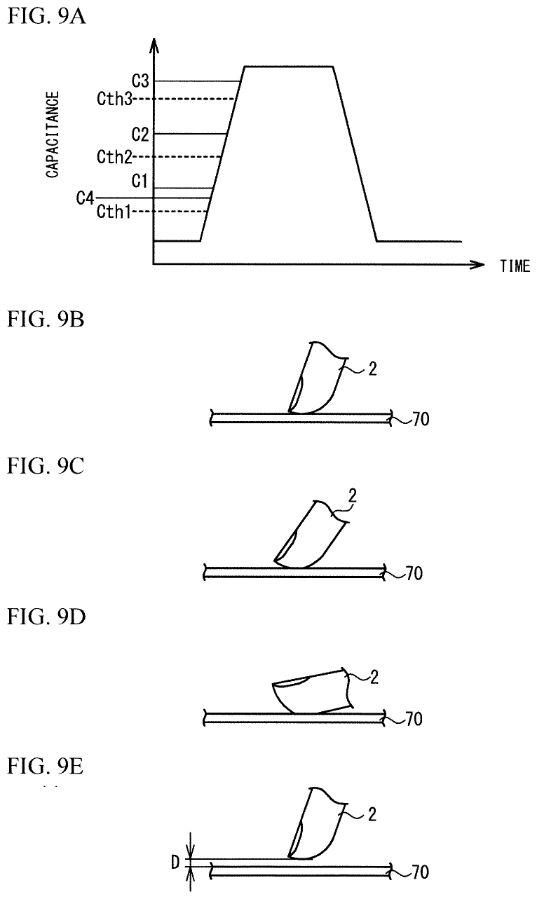

FIG. 9A is a diagram illustrating a change in capacitance. The horizontal axis represents time, and the vertical axis represents the capacitance between the electrodes 74 and 76. FIGS. 9B to 9E are schematic diagrams illustrating an input operation, and illustrate the user's finger 2 and the touch panel 70. The contact area between the finger 2 and the touch panel 70 increases from FIG. 9B toward FIG. 9D, and the capacitance also increases according to this. In FIG. 9B, the contact area between the finger 2 and the touch panel 70 is small, and the capacitance is C1. In FIG. 9C, the contact area is large, and the capacitance is C2 larger than the C1. In FIG. 9D, the contact area is further large, and the capacitance is C3 larger than the C2.

In FIGS. 9B to 9D, the finger 2 touches the touch panel 70. On the other hand, in FIG. 9E, the finger 2 does not touch the touch panel 70, and is away from the touch panel 70 by a distance D. Even if the user does not touch the touch panel 70 as illustrated in FIG. 9E, the capacitance is changed by the finger 2 approaching the touch panel 70, and therefore it is possible to detect the input operation. It is assumed that, in FIG. 9E, the capacitance is C4 smaller than the C1.

In the second embodiment, the processing illustrated in FIG. 6 is performed, the areas having different sensitivities are formed on the keyboard as illustrated in FIGS. 4A to 5B. The sensitivity is the threshold value of an electrostatic capacitance illustrated in FIG. 9A. The higher the threshold value, the lower the sensitivity. The lower the threshold value, the higher the sensitivity. The sensitivity controller 34 increases the sensitivity of the area 53 of the keyboard 50 illustrated in FIG. 4A, lowers the sensitivity of the area 54 than that of the area 53, and lowers the sensitivity of the area 55 than that of the area 54. Specifically, the sensitivity controller 34 determines Cth1 to Cth3 as the threshold values of the areas 53 to 55, respectively. As in the tables 1 to 5, the ROM 14 stores a data table including the layout of the keyboard and the sensitivity for each area.

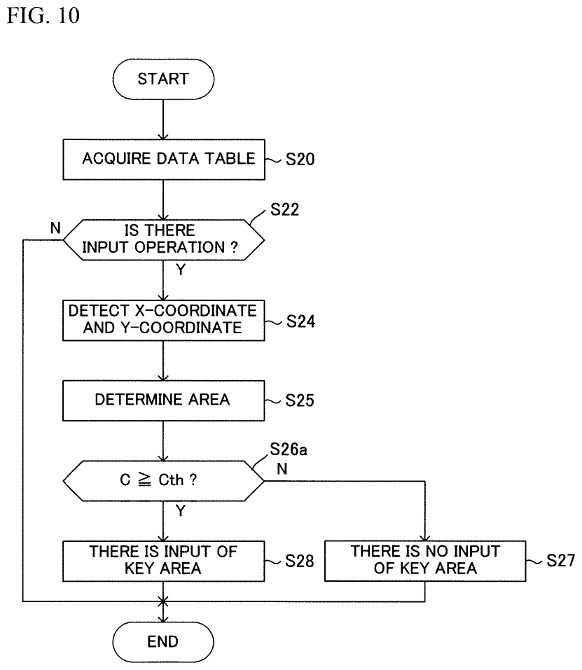

FIG. 10 is a flowchart illustrating detection processing of the input. In FIG. 10, the processing of S26a is performed in place of S26 in FIG. 7. The processings of S20 to S25 are the same as those of FIG. 7. The input detector 38 determines whether the capacitance C (i.e., an input value) at the time of the input operation is equal to or more than the threshold value Cth (S26a). Any one of the Cth1 to Cth3 is assigned to the threshold value Cth depending on the area to be operated. When the answer to the determination of S26a is No, the input detector 38 determines that there is no key input (S27). On the other hand, when the answer to the determination of S26a is Yes, the input detector 38 determines that there is key input (S28). After S27 or S28, the processing is terminated.

According to the second embodiment, the operation feeling is improved in the same manner as the first embodiment. Since the touch panel 70 is an electrostatic capacitance type, the sensitivity controller 34 determines the threshold value of the capacitance as a sensitivity. It is possible to lower the sensitivity of the area by increasing the threshold value, and it is possible to increase the sensitivity of the area by lowering the threshold value. In particular, even if the user does not touch the touch panel 70 as illustrated in FIG. 9 E, the capacitance is the C4 by approaching the finger to the touch panel 70 within the distance D. By lowering the threshold value Cth1 than the C4, it is possible to detect the input even if the user does not touch the touch panel. Thereby, the operation feeling is further improved.

Also in the second embodiment, the sensitivities in the end parts and the central part of the keyboard may be changed each other, and the sensitivities may be changed depending on the user's fingers, in the same manner as the first embodiment. Especially, for the area where the user wants to increase the sensitivity, it is preferable that the threshold value is set to the Cth1 which is the smallest threshold value in FIG. 9A. In such an area, it is possible to perform the key input by only approaching the finger to the touch panel 70. Conversely, in order to not be able to enter the key as long as the finger does not touch the touch panel 70, the threshold value for the area may be increased.

In the first and the second embodiments, three areas having different sensitivities are formed on the keyboard, but two areas or four or more areas may be formed on the keyboard, for example. Here, each key such as the character of the keyboard may be displayed as an image on the display of the touch panel, or may be printed on a sheet to be pasted on the surface of the touch panel, for example. A touch panel other than the resistance film type touch panel and the electrostatic capacitance type touch panel may be used. The user may touch the touch panel with the user's body such as the finger, or may input using a pen. The user may perform the setting such as the sensitivity of the input device 100 from the PC 1, or may perform the setting such as the sensitivity of the input device 100 by operating the input device 100.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. An input device comprising:
an inputter including a plurality of keys;
a sensitivity controller that determines a sensitivity of input operation to the keys;
an input detector that detects the presence or absence of input to the keys based on the input operation and the sensitivity; and
an area controller that sets one or more input areas including at least one key to the inputter;
wherein the sensitivity controller sets the sensitivity for each input area.

2. The input device as claimed in claim 1, wherein
each of the input areas includes two or more keys adjacent to each other.

3. The input device as claimed in claim 1, wherein
the area controller determines the input areas based on the placement of user's fingers on the inputter.

4. An input device comprising:
an electrostatic capacitance type touch panel including a plurality of keys;
a sensitivity controller that determines a sensitivity of input operation to the keys; and
an input detector that detects input to the keys when an input value by the input operation is equal to or more than a threshold value;
wherein the keys includes a first key and a second key, and
the sensitivity controller makes a threshold value corresponding to the first key smaller than a threshold value corresponding to the second key, and an input value when a finger approaches the first key within a predetermined distance.
